(19) United States
(12) Patent Application Publication
(10) Pub. No.: US 2008/0160784 A1
(43) Pub. Date: Jul. 3, 2008

(54) METHOD OF MANUFACTURING SEMICONDUCTOR DEVICE

(75) Inventor: Young Ho Yang, Chungcheongbuk-do (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX SEMICONDUCTOR INC., Icheon-si (KR)

(21) Appl. No.: 11/760,085

(22) Filed: Jun. 8, 2007

(30) Foreign Application Priority Data
Dec. 28, 2006 (KR) 2006-136257

(51) Int. Cl. H01L 21/31

(52) U.S. Cl. 438/763; 257/E21.24

(57) ABSTRACT

A method of manufacturing a semiconductor device for minimizing stress applied to a gate oxide layer or a tunnel oxide layer includes the steps of providing a semiconductor substrate in which a semiconductor device including a word line is formed, forming a capping layer including a first insulating layer having a compressive characteristic and a second insulating layer having a tensile characteristic on an entire surface of the substrate including the word line, and forming an interlayer insulating layer on the capping layer. In another aspect, the method also includes the steps of providing a semiconductor substrate in which a semiconductor device including a word line is formed, forming a capping layer on the entire surface including the word line by alternately forming a first insulating layer of a PECVD method and a second insulating layer of a LPCVD method, and forming an interlayer insulating layer on the capping layer.

### CROSS-REFERENCES TO RELATED APPLICATIONS

The present application claims priority to Korean patent application number 10-2006-136257, filed on Dec. 28, 2006, which is incorporated by reference in its entirety.

### BACKGROUND OF THE INVENTION

The present invention relates, in general, to semiconductor devices and, more particularly, to a method of manufacturing a semiconductor device, in which it can minimize stress applied to a gate oxide layer or a tunnel oxide layer.

A flash memory device is a non-volatile memory device whose data is not lost although the supply of power is stopped. The gate of the flash memory device basically includes a tunnel insulating layer or a tunnel oxide layer, a charge storage layer, a dielectric layer and a control gate. The flash memory device stores, reads or deletes data through a program operation, a read operation and an erase operation. A factor that has the greatest influence on the characteristics of these operations is the tunnel insulating layer. At the time of the program operation or the erase operation, electrons pass are stored in the charge storage layer through the tunnel insulating layer, or are discharged from the charge storage layer to the substrate. Meanwhile, at the time of the read operation, the standby mode or when the supply of power is stopped, electrons trapped at the charge storage layer should not be discharged outside the charge storage layer. If electrons trapped at the charge storage layer are discharged outwardly, stored data is not retained, but changed. That is, if electrons are discharged from the charge storage layer of a programmed memory cell to the outside, the threshold voltage of the memory cell is lowered. Due to this, the status of the stored data changes from “0” to “1”. In the case where the characteristic of the tunnel insulating layer is not good as described above, a good data storage capability cannot be obtained. Thus, it is required to form a tunnel insulating layer having good characteristics.

However, although a tunnel insulating layer having good characteristics is formed, the characteristics of the tunnel insulating layer can be degraded by a subsequent process. For example, after word lines are formed, an insulating layer deposition process for forming a source contact plug and a drain contact plug, a conductive layer deposition process and an etch process for patterning are repeatedly performed several times. In the process of forming the insulating layer, byproducts including hydrogen and/or oxygen are generated. The byproducts are infiltrated into the tunnel insulating layer, degrading the characteristics of the tunnel insulating layer. Plasma is also generated during the etch process. The plasma generated during the etch process is also a major factor to degrade the characteristics of the tunnel insulating layer.

### BRIEF SUMMARY OF THE INVENTION

Accordingly, the present invention addresses the above problems, and discloses a method of manufacturing a semiconductor device, in which a multi-layer capping layer including at least one compressive capping layer and at least one tensile capping layer is formed to offset compressive stress and tensile stress respectively, thereby minimizing stress of the capping layer to a gate insulating layer of word lines or select lines and thus improving electrical characteristics of the device.

In an aspect, a method of manufacturing a semiconductor device includes the steps of providing a semiconductor substrate in which a semiconductor device including a word line is formed, forming a capping layer including a first insulating layer having a compressive characteristic and a second insulating layer having a tensile characteristic on the entire surface including the word line, and forming an interlayer insulating layer on the capping layer.

In another aspect, a method of manufacturing a semiconductor device includes the steps of providing a semiconductor substrate in which a semiconductor device including a word line is formed, forming a capping layer on the entire surface including the word line by alternately forming a first insulating layer of a PECVD method and a second insulating layer of a LPCVD method, and forming an interlayer insulating layer on the capping layer.

In still another aspect, a method of manufacturing a semiconductor device includes the steps of providing a semiconductor substrate in which word lines and source select lines are formed, forming a junction region in the semiconductor substrate between the select lines and the word lines, forming spacers on sidewalls of the word lines and the select lines, forming a capping layer including a first insulating layer having a compressive characteristic and a second insulating layer having a tensile characteristic on the entire surface including the spacers, and forming an interlayer insulating layer on the capping layer.

In further another aspect, a method of manufacturing a semiconductor device includes the steps of providing a semiconductor substrate in which word lines and source select lines are formed, forming a junction region in the semiconductor substrate between the select lines and the word lines, forming spacers on sidewalls of the word lines and the select lines, forming a capping layer on the entire surface including the spacers by alternately forming a first insulating layer of a PECVD method and a second insulating layer of a LPCVD method, and forming an interlayer insulating layer on the capping layer.

### BRIEF DESCRIPTION OF THE DRAWINGS

FIGS. 1A to 1E are cross-sectional views illustrating a method of manufacturing a semiconductor device according to an embodiment of the present invention.

### DESCRIPTION OF SPECIFIC EMBODIMENTS

Now, a specific embodiment according to the present invention will be described with reference to the accompanying drawings.

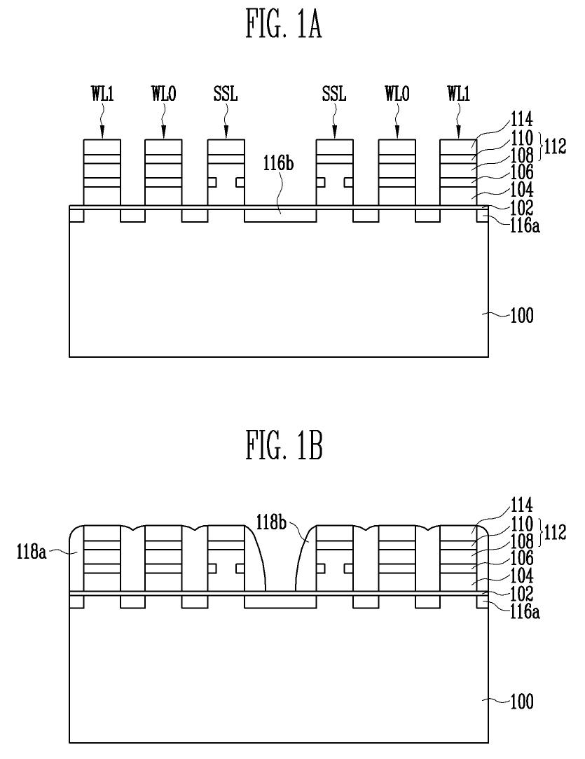

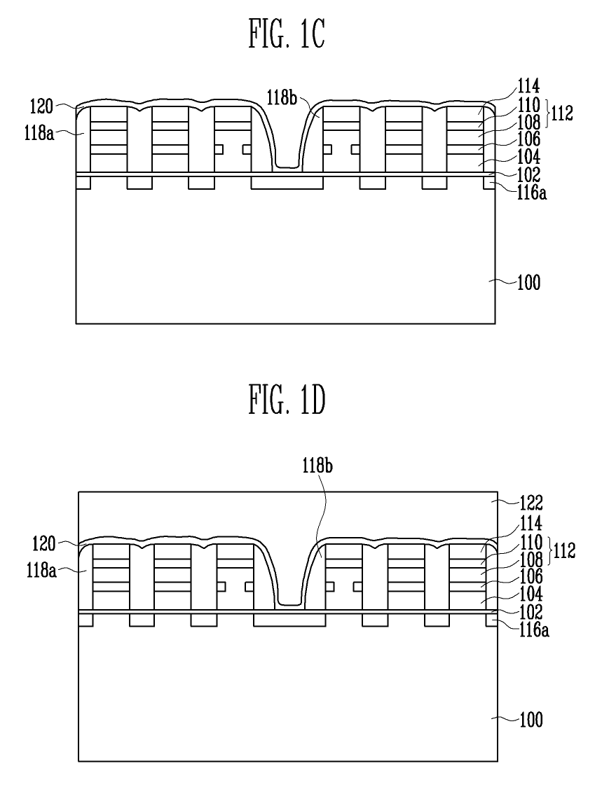

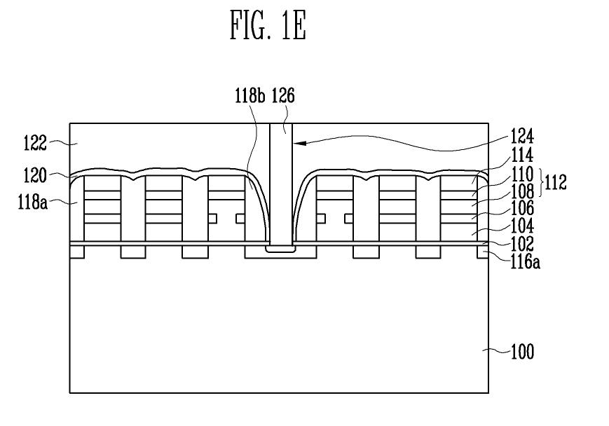

FIGS. 1A to 1E are cross-sectional views illustrating a method of manufacturing a semiconductor device according to an embodiment of the present invention.

Referring to FIG. 1A, a plurality of source select lines SSL, a plurality of word lines WL0 and WL1, and a plurality of drain select lines (not illustrated) are formed over a semiconductor substrate 100. The word lines WL0 and WL1 are formed between the source select lines SSL and drain select lines (not illustrated). In this case, 16, 32 or 64 word lines are formed between the source select lines SSL and the drain select lines (not illustrated). For convenience of description, only two word lines WL0 and WL1 are illustrated in the drawings. Both the source select lines SSL and the drain select lines will be hereinafter referred to as “select lines”. The word lines WL0 and WL1 and the select lines include a tunnel insulating layer 102, a charge storage layer 104, a dielectric layer 106 and a control gate 112. The control gate 112 includes a polysilicon layer 108 and a silicide layer 110. A hard mask 114 is formed on the word lines WL0 and WL1 and the select lines.

An isolation layer (not illustrated) is formed in an isolation region of the semiconductor substrate 100. The isolation layer crosses the word lines WL0 and WL1 and the select lines. Junction regions 116a are also formed in the active region of the semiconductor substrate 100 between the word lines WL0 and WL1 and the select lines. A junction region 116b formed between the source select lines SSL becomes a common source, and the junction region (not illustrated) formed between the drain select lines (not illustrated) becomes a drain.

The charge storage layer 104 and the control gate 112 have to be electrically connected because the select lines have to be formed together with the gate of a transistor. To this end, the dielectric layer 106 is formed on the entire surface including the charge storage layer 104. Before the control gate 112 is formed, a portion of the dielectric layer 106 is removed from a region in which the select lines are formed. Thus, a contact hole is formed in the dielectric layer 106. The charge storage layer 104 and the control gate 112 are electrically connected through the contact hole in the select lines.

The tunnel insulating layer 102 can be formed to a thickness of 50 to 100 angstrom by oxidizing the surface of the semiconductor substrate 100 under a mixed gas atmosphere including O₂ and H₂. After the tunnel insulating layer 102 is formed, a thermal treatment process can be performed under NO or N₂O atmosphere at a temperature of 850 to 950 degrees Celsius in order to improve the film quality of the tunnel insulating layer 102. The charge storage layer 104 can be formed from polysilicon or amorphous silicon, and can be formed to a thickness of 500 to 2500 angstrom by using SiH₄ or SiH₂Cl₂ as a source. Furthermore, when the charge storage layer 104 is formed, boron (B) or phosphor (P) can be supplied additionally so that an impurity concentration of the charge storage layer 104 becomes 1.0E19 atoms/cm³ to 5.0E20 atoms/cm³. The dielectric layer 106 includes an oxide layer and a nitride layer, and can have an oxide layer/a nitride layer/an oxide layer (ONO) structure. In this case, the oxide layer can be formed at a temperature of 600 to 850 degrees Celsius by means of a LPCVD method or ALD method, and the nitride layer can be formed at a temperature of 600 to 750 degrees Celsius by means of a LPCVD method or ALD method by using a source gas, such as SiH₄ or SiH₂Cl₂, and a reaction gas, such as N₂O or NH₃. After the dielectric layer 106 is formed, a thermal treatment process can be performed under oxygen atmosphere in order to remove sources that cause the leakage current at the interface of the oxide layer and the nitride layer. In the concrete, the thermal treatment process can be performed under atmosphere including O₂ and H₂ at a temperature of 600 to 900 degrees Celsius. The hard mask 114 can have a stack structure of an oxide layer and a nitride layer.

Referring to FIG. 1B, spacers 118a and 118b are formed using an insulating layer on the sidewalls of the word lines WL0 and WL1 and the select lines. In the concrete, after the insulating layer is formed on the entire surface in order to fill between the word lines WL0 and WL1, a blanket etch process is performed. If the blanket etch process is performed, the distance between the source select lines SSL and the distance between the drain select lines are relatively wide and, therefore, the insulating layer remains in the form of the spacers 118b on the sidewalls opposite to the source select lines SSL and on the sidewalls opposite to the drain select lines. The common source 116b and the drain (not illustrated) are exposed between the spacers 118b. Further, since the distance between the word lines WL0 and WL1 and the distance between the word lines and the select lines is relatively narrow, the spacers 118a are brought in contact with each other, and the insulating layer 118a is filled between the word lines WL0 and WL1 and between the word lines and the select lines. Accordingly, as the spacers 118a are brought in contact with each other, the junction region between the word lines WL0 and WL1 and the junction region between the word lines and the select lines are not exposed.

In the above, the spacers 118a and 118b can be formed from an oxide layer. Furthermore, the spacers 118a and 118b can have a stack structure of an oxide layer and a nitride layer. In this case, the oxide layer may be first formed such that it is brought in contact with the word lines WL0 and WL1.

Referring to FIG. 1C, a capping layer 120 is formed on the entire surface including the word lines WL0 and WL1. The capping layer 120 serve to protect the word lines or the select line, in particular, the gate insulating layer from plasma damage occurring in a subsequent process. The capping layer 120 can be formed from a nitride layer (Si₃N₄). Meanwhile, even if the capping layer 120 is formed from any layer, the capping layer 120 has a compressive characteristic or a tensile characteristic. Accordingly, the capping layer 120 is formed to have a multi-layer having at least one layer with a compressive characteristic and at least one layer with a tensile characteristic by controlling process conditions. As the capping layer 120 is formed to have the multi-layer, a compressive characteristic and a tensile characteristic are offset to minimize stress applied to the word lines WL0 and WL1 or the select lines. An example in which the capping layer 120 is formed using the nitride layer is described below.

In the case where the capping layer 120 is formed from a nitride layer, the nitride layer is formed using any one of SiH₄, Si₂H₆ and SiH₂Cl₂ and a nitrogen-containing gas (for example, NH₃) at a temperature of 500 to 850 degrees Celsius. At this time, if the nitride layer is formed by a LPCVD method, it has a tensile characteristic. If the nitride layer is formed by a PECVD method, it has a compressive characteristic. If the nitride layer is formed by a different method as described above, the nitride layer having the tensile characteristic and the nitride layer having the compressive characteristic can be formed in multiple layers.

In this case, if the nitride layer is formed by the LPCVD method, a high step coverage ratio can be obtained. If the nitride layer is formed by the PECVD method, a relatively low step coverage ratio can be obtained. Since the step coverage characteristics are compensated for each other, a good step coverage characteristic can be obtained. The capping layer 120 can be formed to have a compressive-tensile-compressive-tensile (C-T-C-T) structure or a tensile-compressive-tensile-compressive (T-C-T-C) structure through the above method. The PECVD method and the LPCVD method are repeated until the capping layer 120 has a target thickness, thus forming the nitride layer.

Referring to FIG. 1D, an interlayer insulating layer 122 is formed on the entire surface.

Referring to FIG. 1E, some of the interlayer insulating layer 122 and the capping layer 120 are removed so that the common source 116b is exposed, forming a source contact hole 124. The source contact hole 124 is formed in a line form parallel to the source select lines SSL, and thus exposes the common source of a neighboring string. The source contact hole 124 is filled with conductive material to form a common source line 126. The common source line 126 can be formed from metal material, such as tungsten, or polysilicon. If the common source line 126 is formed from metal material, such as tungsten, a plug ion implantation process can be performed before the common source line 126 is formed for the purpose of ohmic contact with the common source 116b. When the plug ion is implanted, a 5-valence impurity is implanted. A 5-valence impurity with a concentration higher than that of an impurity implanted into the common source 116b is implanted. Accordingly, the plug ion implantation layer is formed in the common source 116b.

In the above, the capping layer serves to prevent plasma damage, which is generated while the etch process is performed or conductive material is deposited in order to form the interlayer insulating layer or the contact hole, from being applied to the tunnel insulating layer, or prevent components, such as O₂ or H₂, from infiltrating into the tunnel insulating layer.

The above manufacturing method can also be applied to a process of forming a capping layer before an interlayer insulating layer is formed after word lines are formed in NAND flash memory devices and NOR flash memory devices. Furthermore, the manufacturing method can be applied to a process of forming a capping layer before word lines formed by the gate of a transistor are formed in a semiconductor substrate and an interlayer insulating layer is formed even in a memory device including the transistor in a unit cell, such as DRAM.

As described above, according to the present invention, a capping layer is formed in order to protect plasma damage, generated in a subsequent process, from word lines or select lines before an interlayer insulating layer is formed after the word lines and the select lines are formed. However, the capping layer is formed to have a multi-layer including at least one compressive capping layer and at least one tensile capping layer in order to offset compressive stress and tensile stress. Accordingly, stress of the capping layer, which is applied to a gate insulating layer of the word lines or the select lines, can be minimized, and therefore the electrical characteristics of devices can be improved.

Although the foregoing description has been made with reference to the specific embodiment, it is to be understood that changes and modifications of the present invention may be made by a person having ordinary skill in the art without departing from the spirit and scope of the present invention and appended claims.

What is claimed is:

1. A method of manufacturing a semiconductor device, comprising the steps of:
providing a semiconductor substrate in which a semiconductor device including a word line is formed;
forming a capping layer including a first insulating layer having a compressive characteristic and a second insulating layer having a tensile characteristic on an entire surface of said semiconductor substrate including the word line; and
forming an interlayer insulating layer on the capping layer.

2. The method of claim 1, further comprising the step of forming spacers on sidewalls of the word line before the capping layer is formed.

3. The method of claim 1, wherein the capping layer has a structure in which the first insulating layer and the second insulating layer are alternately laminated.

4. The method of claim 3, wherein the first insulating layer is formed by a PECVD method and the second insulating layer is formed by a LPCVD method.

5. The method of claim 1, wherein the capping layer has a structure in which the second insulating layer and the first insulating layer are alternately laminated.

6. The method of claim 5, wherein the first insulating layer is formed by a PECVD method and the second insulating layer is formed by a LPCVD method.

7. The method of claim 1, wherein the first and the second insulating layers are formed from a nitride layer.

8. The method of claim 7, wherein the nitride layer is formed using any one of SiH₄, Si₂H₆ and SiH₂Cl₂, and a nitrogen-containing gas at a temperature of about 500 to 850 degrees Celsius.

9. The method of claim 8, wherein the nitrogen-containing gas is NH₃ gas.

10. A method of manufacturing a semiconductor device, comprising the steps of:
providing a semiconductor substrate in which word lines and select lines are formed;
forming a junction region in the semiconductor substrate between the select lines and the word lines;
forming spacers on sidewalls of the word lines and the select lines;
forming a capping layer including a first insulating layer having a compressive characteristic and a second insulating layer having a tensile characteristic on an entire surface of said semiconductor substrate including the spacers; and
forming an interlayer insulating layer on the capping layer.

11. The method of claim 10, wherein the capping layer has a structure in which the first insulating layer and the second insulating layer are alternately laminated.

12. The method of claim 11, wherein the first insulating layer is formed by a PECVD method and the second insulating layer is formed by LPCVE method.

13. The method of claim 10, wherein the capping layer has a structure in which the second insulating layer and the first insulating layer are alternately laminated.

14. The method of claim 13, wherein the first insulating layer is formed by a PECVD method and the second insulating layer is formed by LPCVE method.

15. The method of claim 10, wherein the first and the second insulating layers are formed from a nitride layer.

16. The method of claim 15, wherein the nitride layer is formed using any one of SiH₄, Si₂H₆ and SiH₂Cl₂, and a nitrogen-containing gas at a temperature of about 500 to 850 degrees Celsius.

17. The method of claim 16, wherein the nitrogen-containing gas is NH₃ gas.
